(19) United States
(12) Patent Application Publication
(10) Pub. No.: US 2023/0236341 A1
(43) Pub. Date: Jul. 27, 2023

(54) MEMS Deformable Lens Assembly and Process Flow

(71) Applicant: MEMS DRIVE (NANJING) CO., LTD., NANJING (CN)

(72) Inventors: Xiaolei Liu, South Pasadena, CA (US); Guiqin Wang, Arcadia, CA (US)

(21) Appl. No.: 18/158,017

(22) Filed: Jan. 23, 2023

Related U.S. Application Data
(60) Provisional application No. 63/301,941, filed on Jan. 21, 2022.

(51) Int. Cl. G02B 3/14; H10N 30/20

(52) U.S. Cl. CPC G02B 3/14; H10N 30/2047

(57) ABSTRACT

A glass membrane deformation assembly configured to deform a glass membrane includes: a deformable glass membrane having a first surface and a second surface; a piezoelectric layer affixed to a first surface of the deformable glass membrane, wherein the piezoelectric layer is controllably deformable via a voltage potential; a structural member affixed to at least a first portion of the second surface of the deformable glass membrane; and a deformable lens assembly affixed to at least a second portion of the second surface of the deformable glass membrane; wherein the controllably deformation of the piezoelectric layer is configured to controllably deform the deformable glass membrane and the deformable lens assembly.

### RELATED APPLICATION(S)

This application claims the benefit of U.S. Provisional Application No. 63/301,941 filed on 21 Jan. 2022, the contents of which are incorporated herein by reference.

### TECHNICAL FIELD

This disclosure relates to actuators in general and, more particularly, to miniaturized MEMS actuators configured for use within camera packages and methods of making the same.

### BACKGROUND

As is known in the art, actuators may be used to convert electronic signals into mechanical motion. In many applications such as e.g., portable devices, imaging-related devices, telecommunications components, and medical instruments, it may be beneficial for miniature actuators to fit within the small size, low power, and cost constraints of these application.

Micro-electrical-mechanical system (MEMS) technology is the technology that in its most general form may be defined as miniaturized mechanical and electro-mechanical elements that are made using the techniques of microfabrication. The critical dimensions of MEMS devices may vary from well below one micron to several millimeters. In general, MEMS actuators are more compact than conventional actuators, and they consume less power.

### SUMMARY OF DISCLOSURE

In one implementation, a glass membrane deformation assembly configured to deform a glass membrane includes: a deformable glass membrane having a first surface and a second surface; a piezoelectric layer affixed to a surface of the deformable glass membrane, wherein the piezoelectric layer is controllably deformable via a voltage potential; a structural member affixed to at least a first portion of the second surface of the deformable glass membrane; and a deformable lens assembly affixed to at least a second portion of the second surface of the deformable glass membrane; wherein the controllably deformation of the piezoelectric layer configured to controllably deform the deformable glass membrane and the deformable lens assembly.

One or more of the following features may be included. The piezoelectric layer may be configured to controllably deform the deformable glass membrane from a generally planar configuration to a generally convex configuration. The deformable glass membrane may be a circular deformable glass membrane. The piezoelectric layer may be a ring-shaped piezoelectric layer. The piezoelectric layer may be affixed to the surface of the deformable glass membrane via a sputtering technique. The piezoelectric layer may include a first electrode and a second electrode applying the voltage potential. The structural member may be a ring-shaped structural member. The structural member may include one or more of: a metal-based structural member; and a silicon-based structural member. The structural member may be affixed to the second surface of the deformable glass membrane via one or more of: an epoxy; and a bonding technique. The deformable glass membrane may be a quartz-based deformable glass membrane. The deformable lens assembly may be a polymer deformable lens assembly. The deformable lens assembly may include a rigid pillar assembly. A rigid base structure may be affixed to the deformable lens assembly.

In another implementation, a glass membrane deformation assembly configured to deform a glass membrane includes: a deformable glass membrane having a first surface and a second surface; a piezoelectric layer affixed to a surface of the deformable glass membrane, wherein the piezoelectric layer is controllably deformable via a voltage potential; a structural member affixed to at least a first portion of the second surface of the deformable glass membrane; and a deformable lens assembly affixed to at least a second portion of the second surface of the deformable glass membrane; wherein; the controllably deformation of the piezoelectric layer is configured to controllably deform the deformable glass membrane and the deformable lens assembly, the deformable glass membrane is a circular deformable glass membrane, and the piezoelectric layer is a ring-shaped piezoelectric layer.

One or more of the following features may be included. The piezoelectric layer may be configured to controllably deform the deformable glass membrane from a generally planar configuration to a generally convex configuration. The piezoelectric layer may include a first electrode and a second electrode for applying the voltage potential. The structural member may be a ring-shaped structural member. The structural member may include one or more of: a metal-based structural member; and a silicon-based structural member. The deformable glass membrane may be a quartz-based deformable glass membrane. The deformable lens assembly may be a polymer deformable lens assembly. The deformable lens assembly may include a rigid pillar assembly. A rigid base structure may be affixed to the deformable lens assembly.

In another implementation, a method of producing a glass membrane deformation assembly includes: partially fabricating a glass membrane deformation assembly using MEMS process; affixing the glass membrane deformation assembly onto a silicon substrate; inverting the glass membrane deformation assembly; and dispensing a polymer into a cavity section of the glass membrane deformation assembly.

One or more of the following features may be included. A rigid pillar assembly may be installed within the polymer. A rigid base structure may be affixed to the glass membrane deformation assembly. The glass membrane deformation assembly may be cured. Partially fabricating a glass membrane deformation assembly using MEMS process may include: affixing a piezoelectric layer to a surface of a deformable glass membrane; etching a portion of the piezoelectric layer to expose a portion of the surface of the deformable glass membrane; affixing a structural member to a second surface of the deformable glass membrane; and etching a portion of the structural member to expose a portion of the second surface of the deformable glass membrane. Affixing a piezoelectric layer to a surface of a deformable glass membrane may include: sputtering the piezoelectric layer to the surface of the deformable glass membrane. Affixing a structural member to a second surface of the deformable glass membrane may include: affixing the structural member to the second surface of the deformable glass membrane via an epoxy. Affixing a structural member to a second surface of the deformable glass membrane may include; bonding the structural member to the second surface of the deformable glass membrane via a bonding technique.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a perspective view of a MEMS package in accordance with various embodiments of the present disclosure;

FIG. 2A is a diagrammatic view of an in-plane MEMS actuator with the optoelectronic device in accordance with various embodiments of the present disclosure;

FIG. 28 is a perspective view of an in-plane MEMS actuator with the optoelectronic device in accordance with various embodiments of the present disclosure;

FIG. 3 is a diagrammatic view of an in-plane MEMS actuator in accordance with various embodiments of the present disclosure;

FIG. 4 is a diagrammatic view of a comb drive sector in accordance with various embodiments of the present disclosure;

FIG. 5 is a diagrammatic view of a comb pair in accordance with various embodiments of the present disclosure;

FIG. 6 is a diagrammatic view of fingers of the comb pair of FIG. 5 in accordance with various embodiments of the present disclosure;

FIGS. 7A-7C are diagrammatic views of a piezoelectric out-of-plane actuator in accordance with various embodiments of the present disclosure:

FIG. 7D is a diagrammatic view of a piezoelectric in-plane actuator in accordance with various embodiments of the present disclosure;

FIG. 8 is a diagrammatic view of a MEMS package in accordance with various embodiments of the present disclosure:

FIGS. 9A-9D are diagrammatic views of a glass membrane deformation assembly in accordance with various embodiments of the present disclosure:

FIG. 10 is a diagrammatic view of a glass membrane deformation assembly in accordance with various embodiments of the present disclosure:

FIGS. 11A-11B are diagrammatic views of a glass membrane deformation assembly in accordance with various embodiments of the present disclosure;

FIGS. 12A-12B are diagrammatic views of a glass membrane deformation assembly in accordance with various embodiments of the present disclosure;

FIG. 13 is a flowchart of an implementation of a process of manufacturing the glass membrane deformation assembly of FIGS. 9A-9D in accordance with various embodiments of the present disclosure; and

FIG. 14A-14G are diagrammatic views of various states of assembly of the glass membrane deformation assembly of FIGS. 9A-9D in accordance with various embodiments of the present disclosure.

Like reference symbols in the various drawings indicate like elements.

### DETAILED DESCRIPTION OF THE PREFERRED EMBODIMENTS

### System Overview:

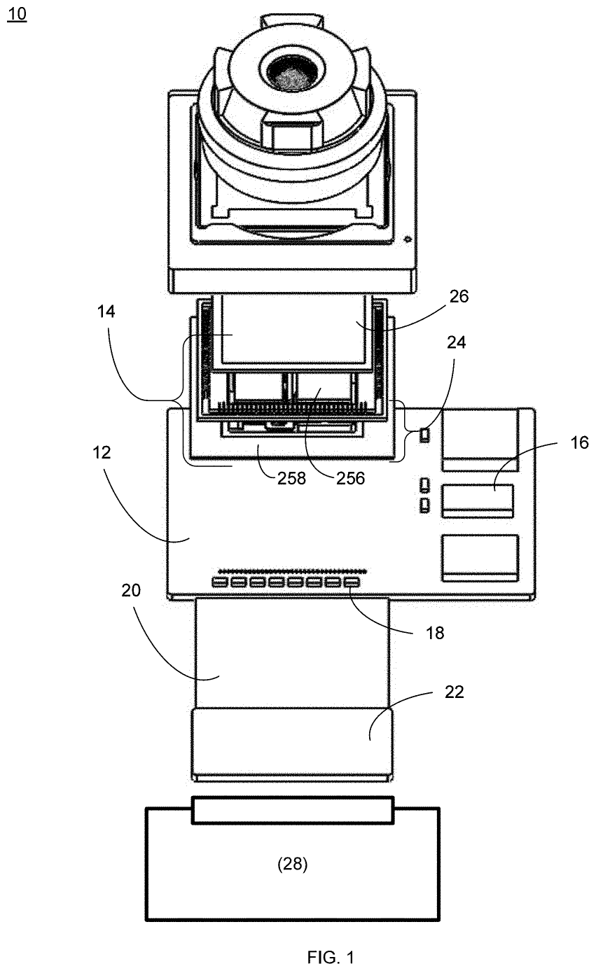

Referring to FIG. 1, there is shown MEMS package 10, in accordance with various aspects of this disclosure. In this example, MEMS package 10 is shown to include printed circuit board 12, multi-axis MEMS assembly 14, driver circuits 16, electronic components 18, flexible circuit 20, and electrical connector 22. Multi-axis MEMS assembly 14 may include micro-electrical-mechanical system (MEMS) actuator 24 (configured to provide linear three-axis movement) and optoelectronic device 26 coupled to micro-electrical-mechanical system (MEMS) actuator 24.

As will be discussed below in greater detail examples of micro-electrical-mechanical system (MEMS) actuator 24 may include but are not limited to an in-plane MEMS actuator, an out-of-plane MEMS actuator, and a combination in-plane/out-of-plane MEMS actuator. For example and if micro-electrical-mechanical system (MEMS) actuator 24 is an in-plane MEMS actuator, the in-plane MEMS actuator may include an electrostatic comb drive actuation system (as will be discussed below in greater detail). Additionally, micro-electrical-mechanical system (MEMS) actuator 24 is an out-of-plane MEMS actuator, the out-of-plane MEMS actuator may include a piezoelectric actuation system or electrostatic actuation. And if micro-electrical-mechanical system (MEMS) actuator 24 is a hybrid in-plane/out-of-plane MEMS actuator, the combination in-plane/out-of-plane MEMS actuator may include an electrostatic comb drive actuation system and a piezoelectric actuation system.

As will be discussed below in greater detail, examples of optoelectronic device 26 may include but are not limited to an image sensor, a holder assembly, an IR filter and/or a lens assembly. Examples of electronic components 18 may include but are not limited. to various electronic or semiconductor components and devices. Flexible circuit 20 and/or connector 22 may be configured to electrically couple MEMS package 10 to e.g., a smart phone or a digital camera (represented as generic item 28).

In some embodiments, some of the components of MEMS package 10 may be joined together using various epoxies/adhesives. For example, an outer frame of micro-electrical-mechanical system (MEMS) actuator 24 may include contact pads that may correspond to similar contact pads on printed circuit board 12.

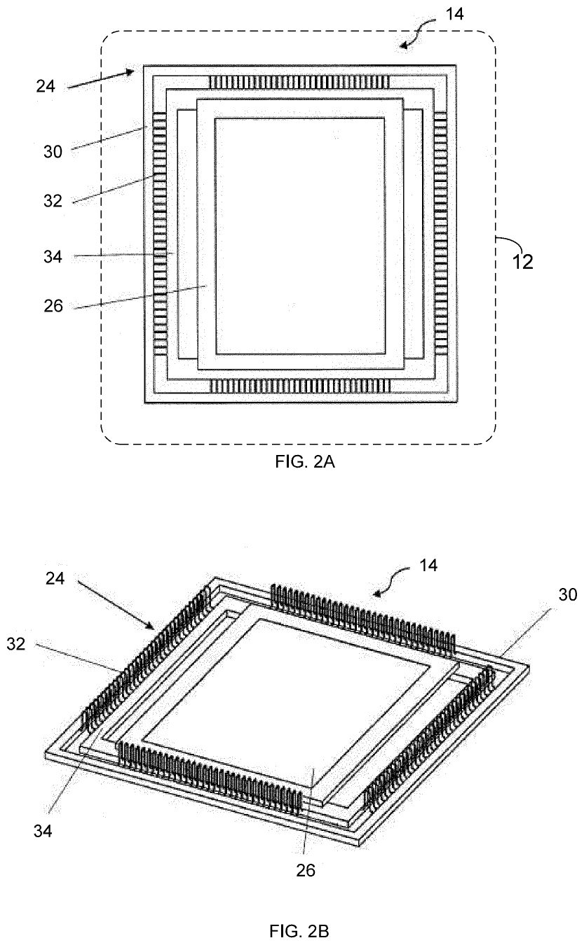

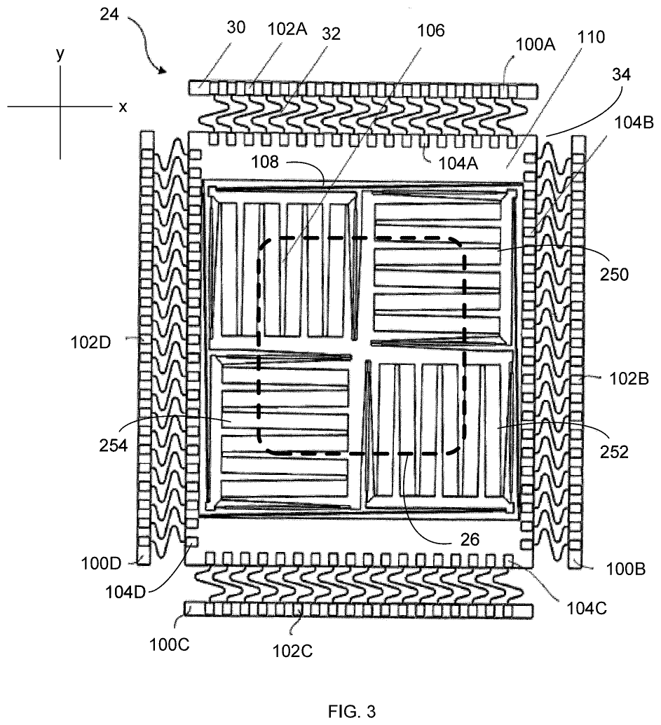

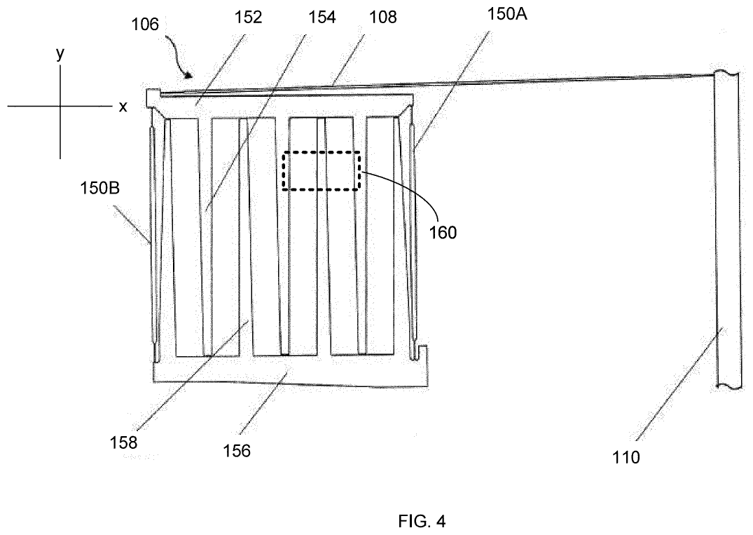

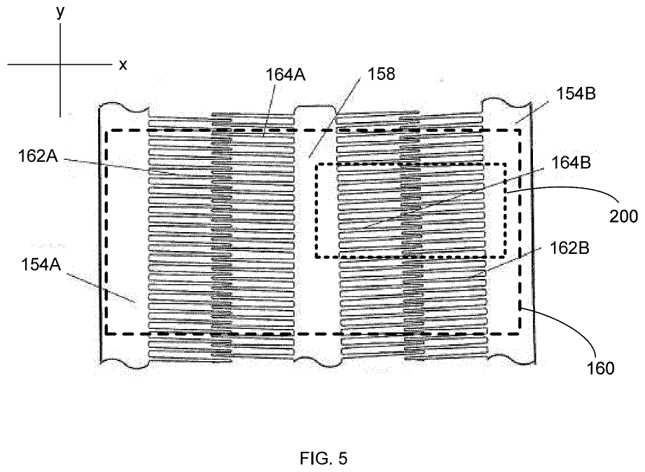

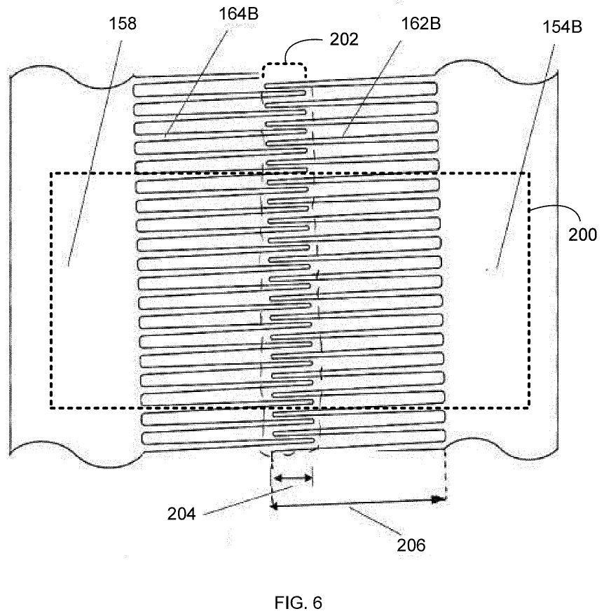

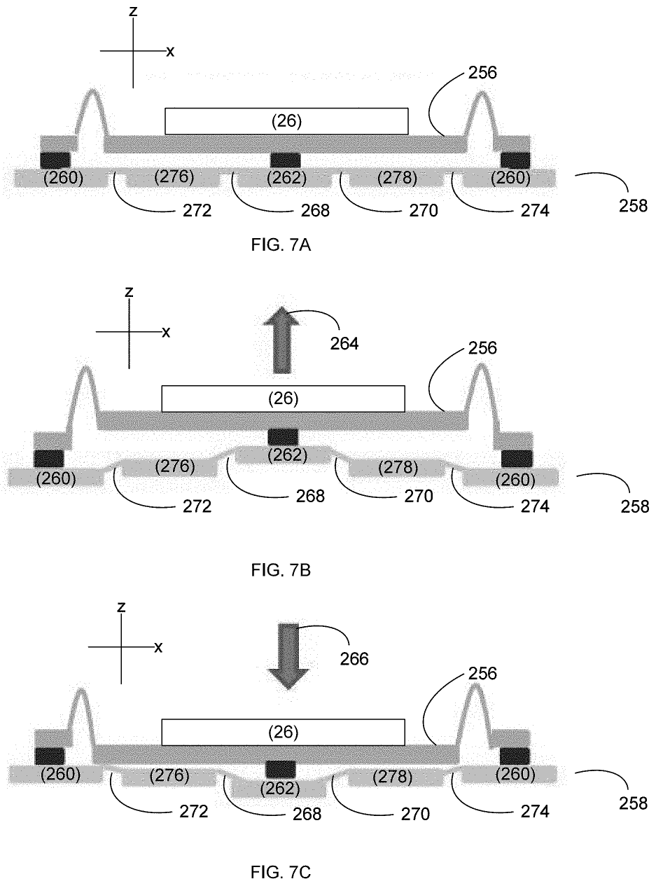

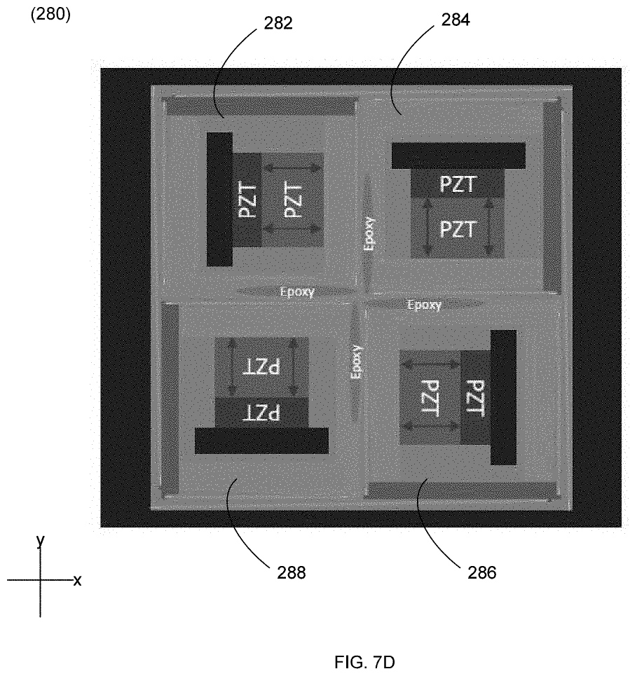

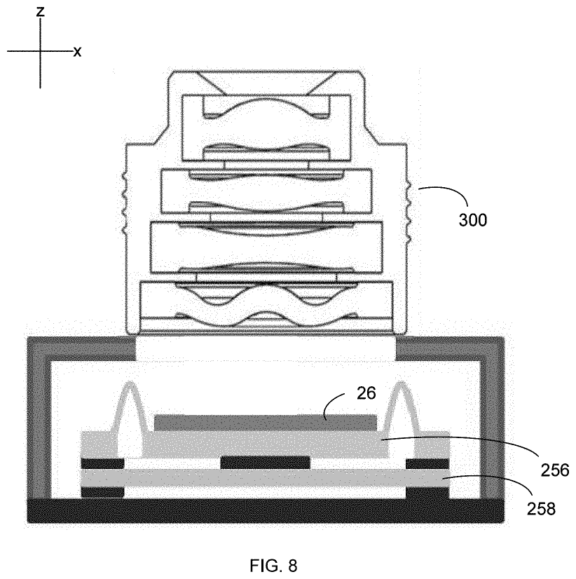

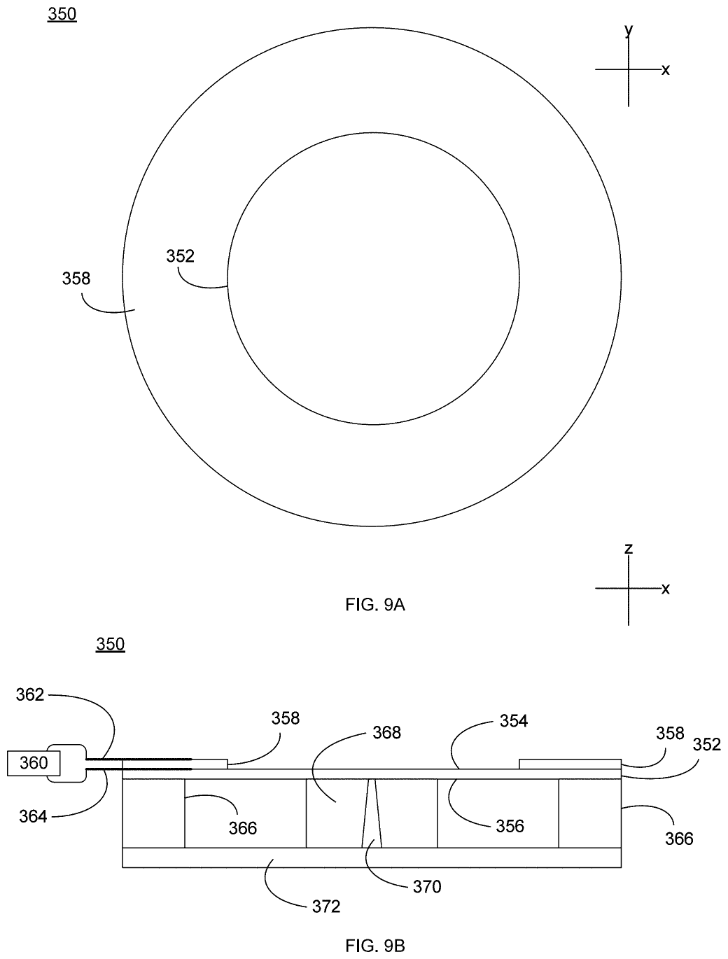

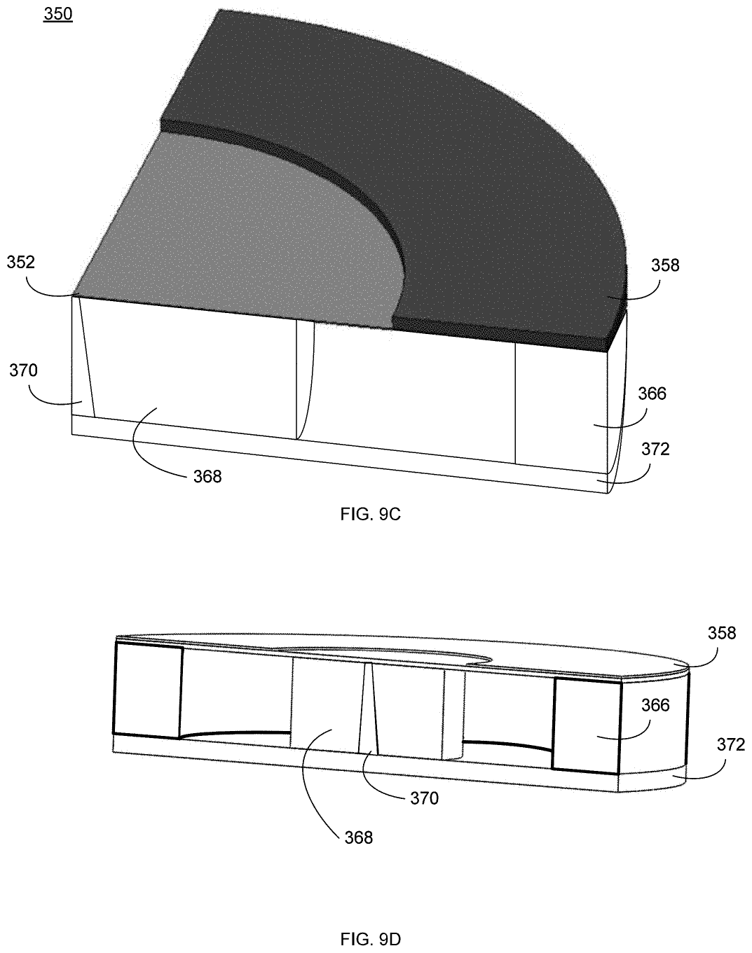

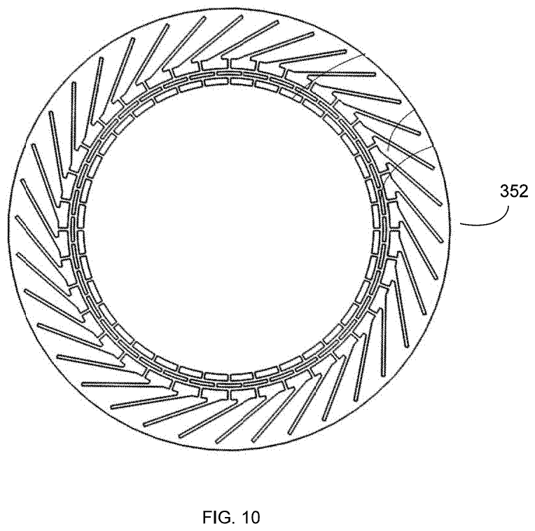

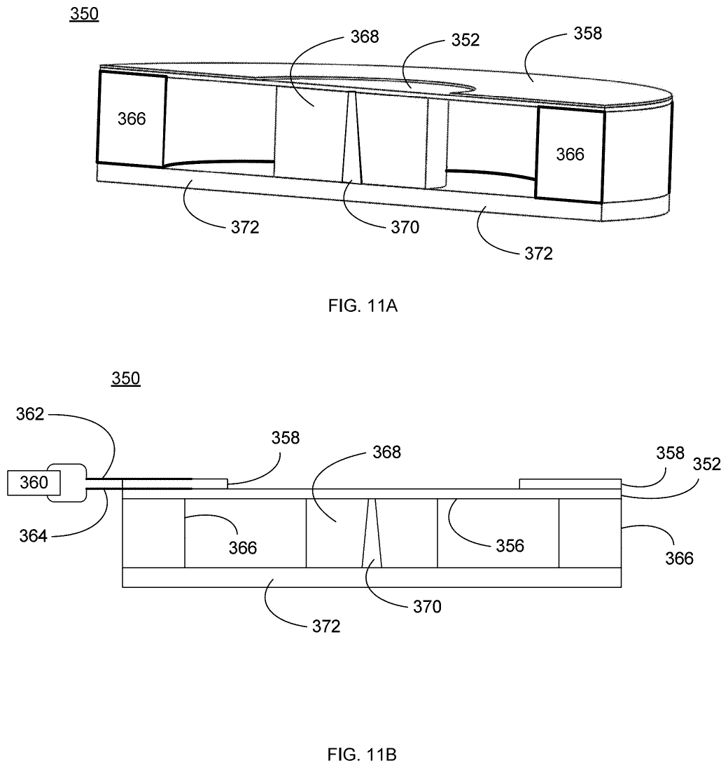

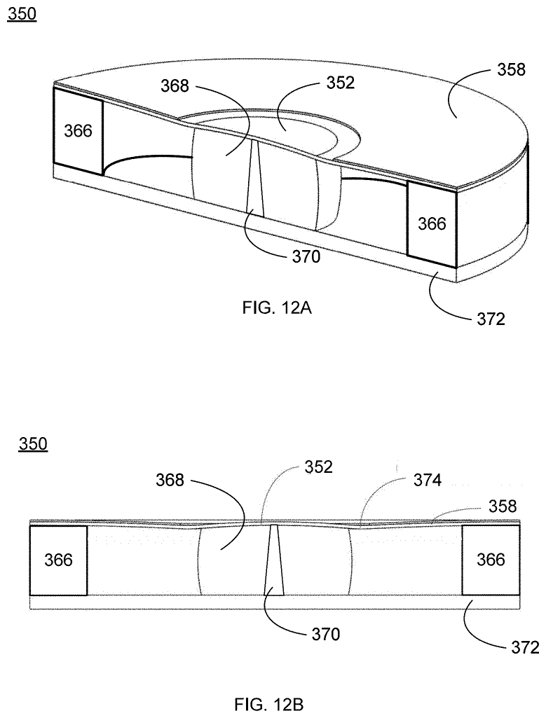

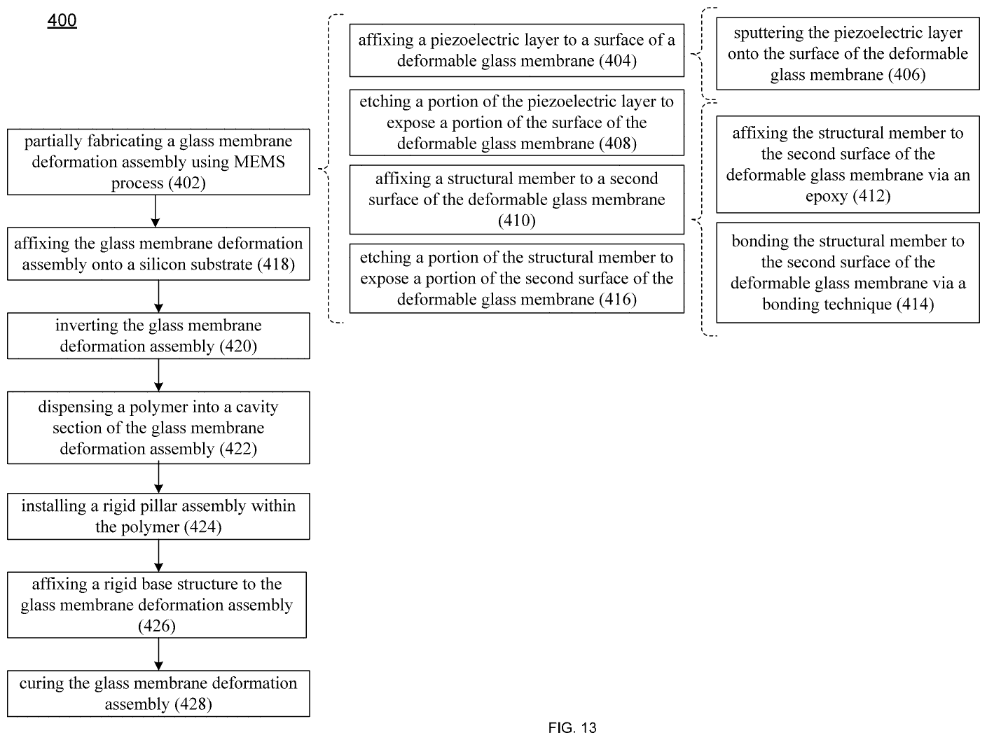

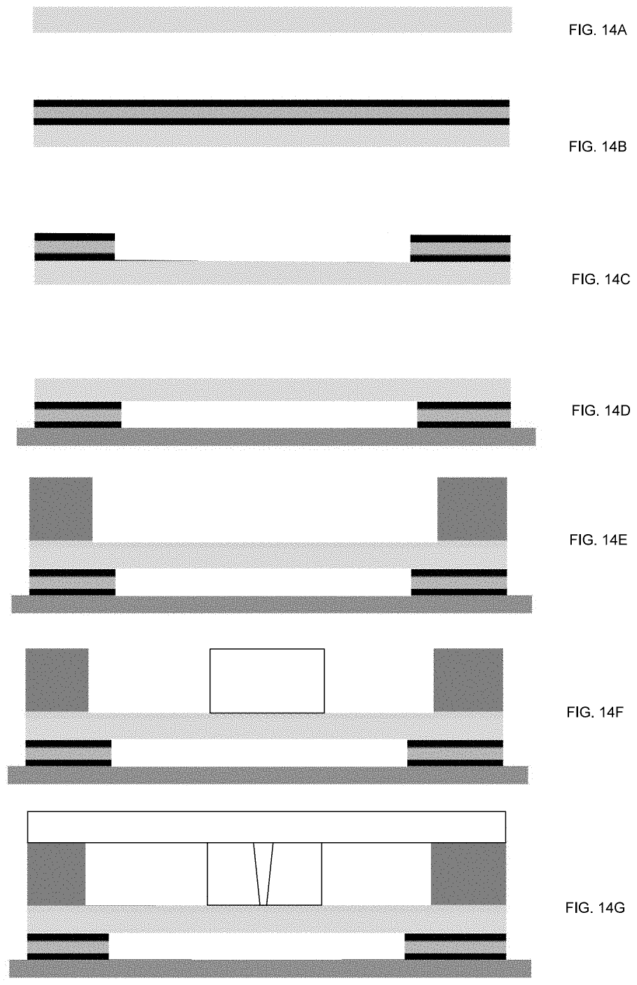

Referring also to FIG. 2A, there is shown multi-axis MEMS assembly 14, which may include optoelectronic device 26 coupled to micro-electrical-mechanical system (MEMS) actuator 24. As discussed above, examples of micro-electrical-mechanical system (MEMS) actuator 24 may include but are not limited to an in-plane MEMS actuator, an out-of-plane MEMS actuator, and a combination in-plane/out-of-plane MEMS actuator.

When configured to provide in-plane actuation functionality, micro-electrical-mechanical system (MEMS) actuator 24 may include outer frame 30, plurality of electrically conductive flexures 32, MEMS actuation core 34 for attaching a payload (e.g., a device), and attached optoelectronic device 26. Optoelectronic device 26 may be coupled to MEMS actuation core 34 of micro-electrical-mechanical system (MEMS) actuator 24 by epoxy (or various other adhesives/materials and/or bonding methods).

Referring also to FIG. 2B, plurality of electrically conductive flexures 32 of micro-electrical-mechanical system (MEMS) actuator 24 may be curved upward and buckled to achieve the desired level of flexibility & compression. In the illustrated embodiment, plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24).

Plurality of electrically conductive flexures 32 may be conductive wires that may extend above the plane (e.g., an upper surface) of micro-electrical-mechanical system (MEMS) actuator 24 and may electrically couple laterally separated components of micro-electrical-mechanical system (MEMS) actuator 24. For example, plurality of electrically conductive flexures 32 may provide electrical signals from optoelectronic device 26 and/or MEMS actuation core 34 to outer frame 30 of micro-electrical-mechanical system (MEMS) actuator 24. As discussed above, outer frame 30 of micro-electrical-mechanical system (MEMS) actuator 24 may be affixed to circuit board 12 using epoxy (or various other adhesive materials or devices).

Referring also to FIG. 3, there is shown a top view of micro-electrical-mechanical system (MEMS) actuator 24 in accordance with various embodiments of the disclosure. Outer frame 30 is shown to include (in this example) four frame assemblies (e.g., frame assembly 100A, frame assembly 100B, frame assembly 100C, frame assembly 100D) that are shown as being spaced apart to allow for additional detail.

Outer frame 30 of micro-electrical-mechanical system (MEMS) actuator 24 may include a plurality of contact pads (e.g., contact pads 102A on frame assembly 100A, contact pads 102B on frame assembly 100B, contact pads 102C on frame assembly 100C, and contact pads 102D on frame assembly 100D), which may be electrically coupled to one end of plurality of electrically conductive flexures 32. The curved shape of electrically conductive flexures 32 is provided for illustrative purposes only and, while illustrating one possible embodiment, other configurations are possible and are considered to be within the scope of this disclosure.

MEMS actuation core 34 may include a plurality of contact pads (e.g., contact pads 104A, contact pads 104B, contact pads 104C, contact pads 104D), which may be electrically coupled to the other end of plurality of electrically conductive flexures 32. A portion of the contact pads (e.g., contact pads 104A, contact pads 104B, contact pads 104C, contact pads 104D) of MEMS actuation core 34 may be electrically coupled to optoelectronic device 26 by wire bonding, silver paste, or eutectic seal, thus allowing for the electrical coupling of optoelectronic device 26 to outer frame 30.

### Electrostatic Actuation

MEMS actuation core 34 may include one or more comb drive sectors (e.g., comb drive sector 106) that are actuation sectors disposed within micro-electrical-mechanical system (MEMS) actuator 24. The comb drive sectors (e.g., comb drive sector 106) within MEMS actuation core 34 may be disposed in the same plane and may be positioned orthogonal to each other to allow for movement in two axes (e.g., the X-axis and the Y-axis). Accordingly, the in-plane MEMS actuator generally (and MEMS actuation core 34 specifically) may be configured to provide linear X-axis movement and linear Y-axis movement.

While in this particular example, MEMS actuation core 34 is shown to include four comb drive sectors, this is for illustrative purposes only and is not intended to be a limitation of this disclosure, as other configurations are possible. For example, the number of comb drive sectors may be increased or decreased depending upon design criteria.

While in this particular example, the four comb drive sectors are shown to be generally square in shape, this is for illustrative purposes only and is not intended to be a limitation of this disclosure, as other configurations are possible. For example, the shape of the comb drive sectors may be changed to meet various design criteria.

While the comb drive sectors (e.g., comb drive sector 106) within MEMS actuation core 34 are shown to be positioned orthogonal to each other to allow for movement in two axes (e.g., the X-axis and the Y-axis), this is for illustrative purposes only and is not intended to be a limitation of this disclosure, as other configurations are possible. For example, the comb drive sectors (e.g., comb drive sector 106) within MEMS actuation core 34 may be positioned parallel to each other to allow for movement in a single axis (e.g., either the X-axis or the Y-axis).

Each comb drive sector (e.g., comb drive sector 106) within MEMS actuation core 34 may include one or more moving portions and one or more fixed portions. As will be discussed below in greater detail, a comb drive sector (e.g., comb drive sector 106) within MEMS actuation core 34 may be coupled, via a cantilever assembly (e.g., cantilever assembly 108), to outer periphery 110 of MEMS actuation. core 34 (i.e., the portion of MEMS actuation core 34 that includes contact pads 104A, contact pads 104B, contact pads 104C, contact pads 104D), which is the portion of MEMS actuation core 34 to Which optoelectronic device 26 may be coupled thus effectuating the transfer of movement to optoelectronic device 26.

Referring also to FIG. 4, there is shown a top view of comb drive sector 106 in accordance with various embodiments of the present disclosure. Each comb drive sector (e.g., comb drive sector 106) may include one or more motion control cantilever assemblies (e.g., motion control cantilever assemblies 150A, 150B) positioned outside of comb drive sector 106, moveable frame 152, moveable spines 154, fixed frame 156, fixed spines 158, and cantilever assembly 108 that is configured to couple moving frame 152 to outer periphery 110 of MEMS actuation core 34. In this particular configuration, motion control cantilever assemblies 150A, 150B may be configured to prevent Y-axis displacement between moving frame 152/moveable spines 154 and fixed frame 156/fixed spines 158.

Comb drive sector 106 may include a movable member including moveable frame 152 and multiple moveable spines 154 that are generally orthogonal to moveable frame 152. Comb drive sector 106 may also include a fixed member including fixed frame 156 and multiple fixed spines 158 that are generally orthogonal to fixed frame 156. Cantilever assembly 108 may be deformable in one direction (e.g., in response to Y-axis deflective loads) and rigid in another direction (e.g., in response to X-axis tension and compression loads), thus allowing for cantilever assembly 108 to absorb motion in the Y-axis but transfer motion in the X-axis.

Referring also to FIG. 5, there is shown a detail view of portion 160 of comb drive sector 106. Moveable spines 154A, 154B may include a plurality of discrete moveable actuation fingers that are generally orthogonally-attached to moveable spines 154A, 154B. For example, moveable spine 154A is shown to include moveable actuation fingers 162A and moveable spine 154B is shown to include moveable actuation lingers 162B.

Further, fixed spine 158 may include a plurality of discrete fixed actuation lingers that are generally orthogonally-attached to fixed spine 158. For example, fixed spine 158 is shown to include fixed actuation fingers 164A that are configured to mesh and interact with moveable actuation fingers 162A. Further, fixed spine 158 is shown to include fixed actuation fingers 164B that are configured to mesh and interact with moveable actuation fingers 162B.

Accordingly, various numbers of actuation fingers may be associated with (i.e., coupled to) the moveable spines (e.g., moveable spines 154A, 154B) and/or the fixed spines (e.g., fixed spine 158) of comb drive sector 106. As discussed above, each comb drive sector (e.g., comb drive sector 106) may include two motion control cantilever assemblies 150A, 150B separately placed on each side of comb drive sector 106. Each of the two motion control cantilever assemblies 150A, 150B may be configured to couple moveable frame 152 and fixed frame 156, as this configuration enables moveable actuation fingers 162A, 162B to be displaceable in the X-axis with respect to fixed actuation fingers 164A, 164B (respectively) while presenting moveable actuation fingers 162A, 162B from being displaced in the Y-axis and contacting fixed actuation fingers 164A, 164B (respectively).

While actuation fingers 162A, 162B, 164A, 164B (or at least the center axes of actuation fingers 162A, 162B, 164A, 164B) are shown to be generally parallel to one another and generally orthogonal to the respective spines to which they are coupled, this is for illustrative purposes only and is not intended to be a limitation of this disclosure, as other configurations are possible. Further and in some embodiments, actuation fingers 162A, 162B, 164A, 164B may have the same width throughout their length and in other embodiments, actuation fingers 162A, 162B, 164A, 164B may be tapered.

Further and in some embodiments, moveable frame 152 may be displaced in the positive X-axis direction when a voltage potential is applied between actuation fingers 162A and actuation fingers 164A, while moveable frame 152 may be displaced in the negative X-axis direction when a voltage potential is applied between actuation fingers 162B and actuation fingers 164B.

Referring also to FIG. 6, there is shown a detail view of portion 200 of comb drive sector 106. Fixed spine 158 may be generally parallel to moveable spine 154B, wherein actuation fingers 164B and actuation fingers 162B may overlap within region 202, wherein the width of overlap region 202 is typically in the range of 10-50 microns. While overlap region 202 is described as being in the range of 10-50 microns, this is for illustrative purposes only and is not intended to be a limitation of this disclosure, as other configurations are possible.

Overlap region 202 may represent the distance 204 where the ends of actuation fingers 162B extends past and overlap the ends of actuation fingers 164B, which are interposed therebetween. In some embodiments, actuation fingers 162B and actuation fingers 164B may be tapered such that their respective tips are narrower than their respective bases (i.e., where they are attached to their spines). As is known in the art, various degrees of taper may be utilized with respect to actuation fingers 162B and actuation lingers 164B. Additionally, the overlap of actuation fingers 162B and actuation fingers 164B provided by overlap region 202 may help ensure that there is sufficient initial actuation force when an electrical voltage potential is applied so that MEMS actuation core 34 may move gradually and smoothly without any sudden jumps when varying the applied voltage. The height of actuation fingers 162B and actuation fingers 164B may be determined by various aspects of the MEMS fabrication process and various design criteria.

Length 206 of actuation fingers 162B and actuation fingers 164B, the size of overlap region 202, the gaps between adjacent actuation fingers, and actuation finger taper angles that are incorporated into various embodiments may be determined by various design criteria, application considerations, and manufacturability considerations, wherein these measurements may be optimized to achieve the required displacement utilizing the available voltage potential.

As shown in FIG. 3 and as discussed above, MEMS actuation core 34 may include one or more comb drive sectors (e.g., comb drive sector 106), wherein the comb drive sectors (e.g., comb drive sector 106) within MEMS actuation core 34 may be disposed in the same plane and may be positioned orthogonal to each other to allow for movement in two axes (e.g., the X-axis and the Y-axis).

Specifically and in this particular example, MEMS actuation core 34 is shown to include four comb drive sectors (e.g., comb drive sectors 106, 250, 252, 254). As discussed above, comb drive sector 106 is configured to allow for movement along the X-axis, while preventing movement along the Y-axis. As comb drive sector 252 is similarly configured, comb drive sector 252 may allow for movement along the X-axis, while preventing movement along the Y-axis. Accordingly, if a signal is applied to comb drive sector 106 that provides for positive X-axis movement, while a signal is applied to comb drive sector 252 that provides for negative X-axis movement, actuation core 34 may be displaced in a clockwise direction. Conversely, if a signal is applied to comb drive sector 106 that provides for negative X-axis movement, while a signal is applied to comb drive sector 252 that provides for positive X-axis movement, actuation core 34 may be displaced in a counterclockwise direction.

Further, comb drive sectors 250, 254 are configured (in this example) to be orthogonal to comb drive sectors 106, 252. Accordingly, comb drive sectors 250, 254 may be configured to allow for movement along the Y-axis, while preventing movement along the X-axis. Accordingly, if a signal is applied to comb drive sector 250 that provides for positive Y-axis movement, while a signal is applied to comb drive sector 254 that provides for negative Y-axis movement, actuation core 34 may be displaced in a counterclockwise direction. Conversely, if a signal is applied to comb drive sector 250 that provides for negative Y-axis movement, while a signal is applied to comb drive sector 254 that provides for positive Y-axis movement, actuation core 34 may be displaced in a clockwise direction.

Accordingly, the in-plane MEMS actuator generally (and MEMS actuation core 34 specifically) may be configured to provide rotational (e.g., clockwise or counterclockwise) Z-axis movement

### Piezoelectric Actuation

As staled above, examples of micro-electrical-mechanical system (MEMS) actuator 24 may include but are not limited to an in-plane MEMS actuator, an out-of-plane MEMS actuator, and a combination in-plane/out-of-plane MEMS actuator. For example and referring also to FIGS. 7A-7C, micro-electrical-mechanical system (MEMS) actuator 24 is shown to include an in-plane MEMS actuator (e.g., in-plane MEMS actuator 256) and an out-of-plane MEMS actuator (e.g., out-of-plane MEMS actuator 258), wherein FIGS. 3-6 illustrate one possible embodiment of in-plane MEMS actuator 256. Optoelectronic device 26 may be coupled to in-plane MEMS actuator 256; and in-plane MEMS actuator 256 may be coupled to out-of-plane MEMS actuator 258.

An example of in-plane MEMS actuator 256 may include but is not limited to an image stabilization actuator. As is known in the art, image stabilization is a family of techniques that reduce blurring associated with the motion of a camera or other imaging device during exposure. Generally, it compensates for pan and tilt (angular movement, equivalent to yaw and pitch) of the imaging device, though electronic image stabilization may also compensate for rotation. Image stabilization may be used in image-stabilized binoculars, still and video cameras, astronomical telescopes, and smartphones. With still cameras, camera shake may be a particular problem at slow shutter speeds or with long focal length (telephoto or zoom) lenses. With video cameras, camera shake may cause visible frame-to-frame jitter in the recorded video. In astronomy, the problem may be amplified by variations in the atmosphere (which changes the apparent positions of objects over time).

An example of out*of-plane MEMS actuator 258 may include but is not limited to an autofocus actuator. As is known in the art, an autofocus system may use a sensor, a control system and an actuator to locus on an automatically (or manually) selected area. Autofocus methodologies may be distinguished by their type (e.g., active, passive or hybrid). Autofocus systems may rely on one or more sensors to determine correct focus, wherein some autofocus systems may rely on a single sensor while others may use an array of sensors.

FIGS. 7A-7C show one possible embodiment of out-of-plane MEMS actuator 258 in various states of activation/excitation. Out-of-plane MEMS actuator 258 may include frame 260 (which is configured to be stationary) and moveable stage 262, wherein out-of-plane MEMS actuator 258 may be configured to provide linear Z-axis movement. For example, out-of-plane MEMS actuator 258 may include a multi-morph piezoelectric actuator that may be selectively and controllably deformable when an electrical charge is applied, wherein the polarity of the applied electrical charge may vary the direction in which the multi-morph piezoelectric actuator (i.e., out-of-plane MEMS actuator 258) is deformed. For example, FIG. 7A shows out-of-plane MEMS actuator 258 in a natural position without an electrical charge being applied. Further, FIG. 7B shows out-of-plane MEMS actuator 258 in an extended position (i.e., displaced in the direction of arrow 264) with an electrical charge having a first polarity being applied, while FIG. 7C shows out-of-plane MEMS actuator 258 in a retracted position (i.e., displaced in the direction of arrow 266) with an electrical charge having an opposite polarity being applied.

As discussed above, the multi-morph piezoelectric actuator (i.e., out-of-plane MEMS actuator 258) may be deformable by applying an electrical charge. In order to accomplish such deformability that allows for such linear Z-axis movement, the multi-morph piezoelectric actuator (i.e., out-of-plane MEMS actuator 258) may include a bending piezoelectric actuator.

As discussed above, the multi-morph piezoelectric actuator (i.e., out-of-plane MEMS actuator 258) may include rigid frame assembly 260 (which is configured to be stationary) and moveable stage 262 that may be configured to be affixed to in-plane MEMS actuator 256. As discussed above, optoelectronic device 26 may be coupled to in-plane MEMS actuator 256 and in-plane MEMS actuator 256 may be coupled to out-of-plane MEMS actuator 258. Accordingly and when out-of-plane MEMS actuator 258 is in an extended position (i.e., displaced in the direction of arrow 264) with an electrical charge having a first polarity being applied (as shown in FIG. 7B), optoelectronic device 26 may be displaced in the positive z-axis direction and towards a leas assembly (e.g., lens assembly 300, FIG. 8). Alternatively and when out-of-plane MEMS actuator 258 is in a retracted position (i.e., displaced in the direction of arrow 266) with an electrical charge having an opposite polarity being applied (as shown in FIG. 7C), optoelectronic device 26 may be displaced in the negative z-axis direction and away from a lens assembly (e.g., lens assembly 300, FIG. 8). Accordingly and by displacing optoelectronic device 26 in the z-axis with respect to a lens assembly (e.g., lens assembly 300, FIG. 8), autofocus functionality may be achieved.

The multi-morph piezoelectric actuator (i.e., out-of-plane MEMS actuator 258) may include at least one deformable piezoelectric portion (e.g., deformable piezoelectric portions 268, 270, 272, 274) configured to couple moveable stage 262 to rigid frame assembly 260.

For example and in one particular embodiment, multi-morph piezoelectric actuator (i.e., out-of-plane MEMS actuator 258) may include a rigid intermediate stage (e.g., rigid intermediate stages 276, 278). A first deformable piezoelectric portion (e.g., deformable piezoelectric portions 268, 270) may be configured to couple rigid intermediate stage (e.g., rigid intermediate gages 276, 278) to moveable stage 262; and a second deformable piezoelectric portion (e.g. deformable piezoelectric portions 272, 274) may be configured to couple the rigid intermediate stage (e.g., rigid intermediate stages 276, 278) to rigid frame assembly 260.

Linear Z-axis (i.e., out-of-plane) movement of moveable stage 262 of out-of-plane MEMS actuator 258 may be generated due to the deformation of the deformable piezoelectric. portion (e.g., deformable piezoelectric portions 268, 270, 274), which may be formed of a piezoelectric material (e.g., PZT (lead zirconate titanate), zinc oxide or other suitable material) that may be configured deflect in response to an electrical signal. As is known in the art, piezoelectric materials are a special type of ceramic that expands or contracts when an electrical field is applied thus generating motion and force.

While out-of-plane MEMS actuator 258 is described above as including a single moveable stage (e.g., moveable stage 262) that enables linear movement in the Z-axis, this is for illustrative purposes only and is not intended to be a limitation of this disclosure, as other configurations are possible and are considered to be within the scope of this disclosure. For example, out-of-plane MEMS actuator 258 may be configured to include multiple moveable stages. For example, if deformable piezoelectric portions 272, 274 were configured to be separately controllable, additional degrees of freedom (such as tip and/or tilt) may be achievable. For example and in such a configuration displacing intermediate stage 276 in an upward direction (i.e., in the direction of arrow 264) While displacing intermediate stage 278 in a downward direction (i.e., in the direction of arrow 266) would result in clockwise rotation of optoelectronic device 26 about the Y-axis; while displacing intermediate stage 276 in a downward direction (i.e., in the direction of arrow 266) while displacing intermediate stage 278 in a upward direction (i.e., in the direction of arrow 264) would result in counterclockwise rotation of optoelectronic device 26 about the Y-axis. Additionally/alternatively, corresponding clockwise and counterclockwise rotation of optoelectronic device 26 about the X-axis may be achieved via additional/alternative intermediate stages.

While FIGS. 7A-7C each show one possible embodiment of an out-of-plane piezoelectric MEMS actuator in various states of activation/excitation, this is for illustrative purposes only and is not intended to be a limitation of this disclosure, as other configurations are possible and are considered to be within the scope of this disclosure. For example and as shown in FIG. 7D, in-plane piezoelectric MEMS actuator 280 may be formed in a fashion similar to that of the above-described in-plane electrostatic MEMS actuators. Accordingly, in-plane piezoelectric MEMS actuator 280 may include a plurality of piezoelectric drive sectors (e.g., piezoelectric drive sectors 282, 284, 286, 288) configured in a similar orthogonal fashion (e.g., piezoelectric drive sectors 282, 286 being configured to enable movement in one axis and piezoelectric drive sectors 284, 288 being configured to enable movement in an orthogonal axis), thus enabling movement in the X-axis and the Y-axis, and rotation about the Z-axis.

### Glass Membrane Deformation Assembly:

As discussed above, optoelectronic device 26 may be coupled to in-plane MEMS actuator 256 and in-plane MEMS actuator 256 may be coupled to out-of-plane MEMS actuator 258. Accordingly and when out-of-plane MEMS actuator 258 is in an extended position (i.e., displaced in the direction of arrow 264) with an electrical charge having a first polarity being applied (as shown in FIG. 7B). optoelectronic device 26 may be displaced in the positive z-axis direction and towards a lens assembly (e.g., lens assembly 300, FIG. 8). Alternatively and when out-of-plane MEMS actuator 258 is in a retracted position (i.e., displaced in the direction of arrow 266) with an electrical charge having an opposite polarity being applied (as shown in FIG. 7C), optoelectronic device 26 may be displaced in the negative z-axis direction and away from a lens assembly (e.g., lens assembly 300, FIG. 8). Accordingly and by displacing optoelectronic device 26 in the z-axis with respect to a lens assembly (e.g., lens assembly 300, FIG. 8), autofocus/zoom functionality may be achieved.

Referring also to FIG. 9A, micro-electrical-mechanical system (MEMS) actuator 24 and/or ♦lens assembly 300 may include a glass membrane deformation assembly (e.g., glass membrane deformation. assembly 350) configured to perform such autofocus functionality. In one exemplary embodiment, glass membrane deformation assembly 350 may be positioned between optoelectronic device 26 and lens assembly 300. In another embodiment, glass membrane deformation assembly 350 may replace one of the lenses within lens assembly 300, and may be configured to vary the focal length of lens assembly 300, thus effectuating such autofocus functionality.

Referring also to FIGS. 9B-9D, glass membrane deformation assembly 350 may be configured to deform a glass membrane. Accordingly, glass membrane deformation assembly 350 may include a deformable glass membrane (e.g., deformable glass membrane 352) having a first surface (e.g., first surface 354) and a second surface (e.g., second surface 356). An example of the deformable glass membrane (e.g., deformable glass membrane 352) may include but is not limited to a quartz-based deformable glass membrane.

A piezoelectric layer (e.g., piezoelectric layer 358) may be affixed to a surface (e.g., first surface 354 or second surface 356) of the deformable glass membrane (e.g., deformable glass membrane 352). This piezoelectric layer (e.g., piezoelectric layer 358) may be controllably deformable via a voltage potential (e.g., from voltage source 360). An example of voltage source 360 may include but is not limited to a DC (i.e., direct current) voltage source configured to provide a DC voltage of sufficient strength (e.g., upwards of 200 volts DC) to effectuate the desired level of deformation of the deformable glass membrane (e.g., deformable glass membrane 352). The piezoelectric layer (e.g., piezoelectric layer 358) may include a first electrode (e.g., first electrode 362) and a second electrode (e.g., second electrode 364) for applying the voltage potential (e.g., from voltage source 360).

An example of the piezoelectric layer (e.g., piezoelectric layer 358) may include but is not limited to a multi-morph piezoelectric layer that may be selectively and controllably deformable when an electrical charge is applied (e.g., from voltage source 360), wherein the polarity of the applied electrical charge (e.g., from voltage source 360) may vary the direction in which the multi-morph piezoelectric layer (e.g., piezoelectric layer 358) is deformed.

The piezoelectric layer (e.g., piezoelectric layer 358) may be affixed to the surface (e.g., first surface 354 or second surface 356) of the deformable glass membrane (e.g., deformable glass membrane 352) via a sputtering technique or any other physical vapor deposition (PVD) technique. As is known in the art, sputtering is a phenomenon in which microscopic particles of a solid material are ejected from its surface after the material is itself bombarded by energetic particles of a plasma or gas.

A structural member (e.g., structural member 366) may be affixed to at least a first portion of the second surface (e.g., second surface 356) of tire deformable glass membrane (e.g., deformable glass membrane 352). The controllable deformation of the piezoelectric layer (e.g., piezoelectric layer 358) may be configured to controllably deform the deformable glass membrane (e.g., deformable glass membrane 352).

The structural member (e.g., structural member 366) may include one or more of: a metal-based structural member (e.g., a nickel structural member or a stainless-steel structural member) and a silicon-based structural member. The structural member (e.g., structural member 366) may be affixed to the second surface of the deformable glass membrane (e.g., deformable glass membrane 352) via an epoxy (or various other adhesives/materials) and/or via a bonding technique (e.g., applying structural member 366 at a specific temperature so that it adheres to deformable glass membrane 352).

In a preferred embodiment, an example of the deformable glass membrane (e.g., deformable glass membrane 352) may include but is not limited to a circular deformable glass membrane; an example of the piezoelectric layer (e.g., piezoelectric layer 358) may include but is not limited to a ring-shaped piezoelectric layer; and an example of the structural member (e.g., structured member 366) may include but is not limited to a ring-shaped structural member.

Glass membrane deformation assembly 350 may include a deformable lens assembly (e.g., deformable lens assembly 368) affixed to at least a second portion of the second surface (e.g., second surface 356) of the deformable glass membrane (e.g., deformable glass membrane 352). Being deformable lens assembly 368 is affixed to deformable glass membrane 352, any controlled deformation of piezoelectric layer 358 (which is also affixed to deformable glass membrane 352) may also controllably deform deformable lens assembly 368.

The deformable lens assembly (e.g., deformable lens assembly 368) may be a polymer deformable lens assembly, An example of such a polymer may include any optically clear polymer, As will be discussed below in great detail, by deforming the shape of deformable lens assembly 368, the focal length of deformable lens assembly 368 may be changed to e.g., effectuate such autofocus functionality.

The deformable lens assembly (e.g., deformable lens assembly 368) may include a rigid pillar assembly (e.g., rigid pillar as 370). Examples of rigid pillar assembly 370 may include a rigid pillar assembly constructed of a higher modulus polymer (when compared to the rest of deformable lens assembly 368) or a piece of optically clear glass or plastic.

A rigid base structure (e.g., rigid. base structure 372) may be affixed to the deformable lens assembly (e.g., deformable lens assembly 368). An example of the rigid base structure (e.g., rigid base structure 372) may include but is not limited to a quartz based glass rigid base structure.

Deformable glass membrane 352 may be processed to make deformable glass membrane 352 more easily deformed. For example, one or more grooves may be etched into deformable glass membrane 352 in the illustrative pattern shown in FIG. 10.

Generally speaking, the piezoelectric layer (e.g., piezoelectric layer 358) may be configured to controllably deform the deformable glass membrane (e.g., deformable glass membrane 352) from a generally planar configuration (as shown in FIGS. 11A-11B) to a generally convex configuration (as shown in FIG. 12A-12B) to e.g., effectuate such autofocus functionality.

For example and for illustrative purposes:
FIGS. 11A-11B illustrates glass membrane deformation assembly 350 when no voltage potential is applied to first electrode 362 and second electrode 364 of the piezoelectric layer (e.g., piezoelectric layer 358), resulting in deformable glass membrane 352 being essential planar.
FIGS. 12A-12B illustrates glass membrane deformation assembly 350 when a voltage potential (e.g., from voltage source 360) having a forward polarity is applied to first electrode 362 and second electrode 364 of the piezoelectric layer (e.g., piezoelectric layer 358). The application of such a forward polarity voltage potential may result in a deformation of piezoelectric layer 358, resulting in a downward force at inflection point 374 and an upward convexity of deformable glass membrane 352 (in the positive Z axis) due to the rigidity of rigid pillar assembly 370. Conversely, the application of a reverse polarity voltage potential to first electrode 362 and second electrode 364 of piezoelectric layer 358 may result in a deformation of piezoelectric layer 358, resulting in an upward force at inflection point 374 and a downward convexity of deformable glass membrane 352 (in the negative Z axis) due to the rigidity of rigid pillar assembly 370.

### Process Flow:

Referring also to FIG. 13, there is shown a method (e.g., method 400) of producing glass membrane deformation assembly 350. Method 400 may utilize a standard thickness piece of glass as the starting point for producing glass membrane deformation assembly 350. As discussed above, an example of such a standard thickness piece of glass may include but is not limited to a quartz-based piece of glass, as shown in FIG. 14A.

Method 400 for producing glass membrane deformation assembly 350 using include: partially fabricating 402 glass membrane deformation assembly 350 using MEMS process. For example, partially fabricating 402 glass membrane deformation assembly 350 may include affixing 404 a piezoelectric layer (e.g., piezoelectric layer 358) to a surface (e.g., first surface 354 or second surface 356) of deformable glass membrane 352 including first electrode 362 and second electrode 364, as shown in FIG. 12B. In one embodiment, piezoelectric layer 358 may be 3 mm thick, wherein electrodes 362 364 may each be 150 nanometers thick.

When affixing 404 a piezoelectric layer (e.g., piezoelectric layer 358) to a surface (e.g., first surface 354 or second surface 356) of deformable glass membrane 352, method 400 may sputter 406 the piezoelectric layer (e.g., piezoelectric layer 358) onto the surface (e.g., first surface 354 or second surface 356) of deformable glass membrane 352. As discussed above, sputtering is a phenomenon in which microscopic particles of a solid material are ejected from its surface after the material is itself bombarded by energetic particles of a plasma or gas. Partially fabricating 402 glass membrane deformation assembly 350 may etching 408 a portion of the piezoelectric layer (e.g., piezoelectric layer 358) to expose a portion of the surface (e.g., first surface 354 or second surface 356) of deformable glass membrane 352, 352), as shown in FIG. 12C

Method 400 for producing glass membrane deformation assembly 350 may include affixing 418 glass membrane deformation assembly 350 onto a silicon substrate and inverting 420 glass membrane deformation assembly 350. For example, method 400 may mount glass membrane deformation assembly 350 (thus far) upside down on a tape assembly, as shown in FIG. 12D. Once inverted, method 400 may thin the deformable glass membrane (e.g., deformable glass membrane 352) to a desired thickness. An example of such a desired thickness for deformable glass membrane 352 may include but is not limited to 20-200 micrometers.

Partially fabricating 402 glass membrane deformation assembly 350 may include affixing 410 a structural member (e.g., structural member 366) to a second surface (e.g., second surface 356) of deformable glass membrane 352, as shown in FIG 12E. As discussed above, an example of the structural member (e.g., structural member 366) may include one or more of: a metal-based structural member (e.g., a nickel structural member or a stainless-steel structural member) and a silicon-based structural member.

When affixing 410 a structural member (e.g., structural member 366) to a second surface (e.g., second surface 356) of the deformable glass membrane (e.g., deformable glass membrane 352), method 400 may:
affix 412 the structural member (e.g., structural member 366) to the second surface (e.g., second surface 356) of the deformable glass membrane (e.g., deformable glass membrane 352) via an epoxy; and/or
bond 414 the structural member (e.g., structural member 366) to the second surface (e.g., second surface 356) of the deformable glass membrane (e.g., deformable glass membrane 352) via a bonding technique.

Partially fabricating 402 glass membrane deformation assembly 350 may include etching 416 a portion of the structural member (e.g., structural member 366) to expose a portion of the second surface (e.g., second surface 356) of deformable glass membrane 352. Specifically, by etching 408 a portion of piezoelectric layer 358 to expose a portion of first surface 354 or second surface 356 of deformable glass membrane 352 and etching 416 a portion of structural member 366 to expose a portion of second surface 356 of deformable glass membrane 352, deformable glass membrane 352 may allow for the passage of light.

Method 400 for producing glass membrane deformation assembly 350 may include dispensing 422 a polymer into a cavity section. of glass membrane deformation assembly 350 (e.g., to form deformable lens assembly 368), as shown in FIG. 14F.

Method 400 for producing glass membrane deformation assembly 350 may include installing 424 a rigid pillar assembly (e.g., rigid pillar assembly 370) within the polymer (e.g., that formed deformable lens assembly 368) and affixing 426 a rigid base structure (e.g., rigid base structure 372) to glass membrane deformation assembly 350, as shown in FIG. 14G. Method 400 for producing glass membrane deformation assembly 350 may include curing 428 glass membrane deformation assembly 350.

### General:

In general, the various operations of method described herein may be accomplished using or may pertain to components or features of the various systems and/or apparatus with their respective components and subcomponents, described herein.

The presence of broadening words and phrases such as “one or more,” “at least” “but not limited to” or other like phrases in some instances shall not be read to mean that the narrower case is intended or required in instances where such broadening phrases may be absent.

Additionally; the various embodiments set forth herein are described in terms of example block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

While various embodiments of the present disclosure have been described above, it should be understood that they have been presented by way of example only, and not of limitation. Likewise, the various diagrams may depict an example architectural or other configuration for the disclosure, which is done to aid in understanding the features and functionality that can be included in the disclosure. The disclosure is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present disclosure. Additionally, with regard to flow diagrams, operational descriptions and method claims, the order in which the steps are presented herein shall not mandate that various embodiments be implemented to perform the recited functionality in the same order unless the context dictates otherwise.

Although the disclosure is described above in terms of various example embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosure, whether or not such embodiments are described and whether or not such features are presented as being a part of a described embodiment. Thus, the breadth and scope of the present disclosure should not be limited by any of the above-described example embodiments, and it will be understood by those skilled in the art that various changes and modifications to the previous descriptions may be made within the scope of the claims.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A glass membrane deformation assembly configured to deform a glass membrane comprising:
a deformable glass membrane having a first surface and a second surface;
a piezoelectric layer affixed to a surface of the deformable glass membrane, wherein the piezoelectric layer is controllably deformable via a voltage potential;
a structural member affixed to at least a first portion of the second surface of the deformable glass membrane; and
a deformable lens assembly affixed to at least a second portion of the second surface of the deformable glass membrane;
wherein the controllably deformation of the piezoelectric layer is configured to controllably deform the deformable glass membrane and the deformable lens assembly.

2. The glass membrane deformation assembly of claim 1 wherein the piezoelectric layer is configured to controllably deform the deformable glass membrane from a generally planar configuration to a generally convex configuration.

3. The glass membrane deformation assembly of claim 1 wherein:
the deformable glass membrane is a circular deformable glass membrane; and
the piezoelectric layer is a ring-shaped piezoelectric layer.

4. The glass membrane deformation assembly of claim 1 wherein the piezoelectric layer is affixed to the surface of the deformable glass membrane via a sputtering technique.

5. The glass membrane deformation assembly of claim 1 wherein the piezoelectric layer includes a first electrode and a second electrode for applying the voltage potential.

6. The glass membrane deformation assembly of claim 1 wherein the structural member is a ring-shaped structural member.

7. The glass membrane deformation assembly of claim 1 wherein the structural member includes one or more of:
a metal-based structural member; and
a silicon-based structural member.

8. The glass membrane deformation assembly of claim 1 wherein the structural member is affixed to the second surface of the deformable glass membrane via one or more of:
an epoxy; and
a bonding technique.

9. The glass membrane deformation assembly of claim 1 wherein the deformable glass membrane is a quartz-based deformable glass membrane.

10. The glass membrane deformation assembly of claim 1 wherein the deformable lens assembly is a polymer deformable lens assembly.

11. The glass membrane deformation assembly of claim 1 wherein the deformable lens assembly includes a rigid pillar assembly.

12. The glass membrane deformation assembly of claim 1 further comprising:
a rigid base structure affixed to the deformable lens assembly.

13. A glass membrane deformation assembly configured. to deform a glass membrane comprising:
a deformable glass membrane having a first surface and a second surface;
a piezoelectric layer affixed to a surface of the deformable glass membrane, wherein the piezoelectric layer is controllably deformable via a voltage potential;
a structural member affixed to at least a first portion of the second surface of the deformable glass membrane, and
a deformable lens assembly affixed to at least a second portion of the second surface of the deformable glass membrane;
wherein:
the controllably deformation of the piezoelectric layer is configured to controllably deform the deformable glass membrane and the deformable lens assembly,
the deformable glass membrane is a circular deformable glass membrane, and
the piezoelectric layer is a ring-shaped piezoelectric layer.

14. The glass membrane deformation assembly of claim 13 wherein the piezoelectric layer is configured to controllably deform the deformable glass membrane from a generally planar configuration to a generally convex configuration.

15. The glass membrane deformation assembly of claim 13 wherein the piezoelectric layer includes a first electrode and a second electrode for applying the voltage potential.

16. The glass membrane deformation assembly of claim 13 wherein the structural member is a ring-shaped structural member.

17. The glass membrane deformation assembly of claim 13 wherein the structural member includes one or more of:
a metal-based structural member; and
a silicon-based structural member.

18. The glass membrane deformation assembly of claim 13 wherein the deformable glass membrane is a quartz-based deformable glass membrane.

19. The glass membrane deformation assembly of claim 13 wherein the deformable lens assembly is a polymer deformable lens assembly.

20. The glass membrane deformation assembly of claim 13 wherein the deformable lens assembly includes a rigid pillar assembly.

21. The glass membrane deformation assembly of claim 13 further comprising:
a rigid base structure affixed to the deformable lens assembly.

22. A method of producing a glass membrane deformation assembly comprising:
partially fabricating a glass membrane deformation assembly using MEMS process;
affixing the glass membrane deformation assembly onto a silicon substrate;
inverting the glass membrane deformation assembly; and
dispensing a polymer into a cavity section of the glass membrane deformation assembly.

23. The method of producing a glass membrane deformation assembly of claim 22 further comprising:
installing a rigid pillar assembly within the polymer.

24. The method of producing a glass membrane deformation assembly of claim 23 further comprising:
affixing a rigid base structure to the glass membrane deformation assembly.

25. The method of producing a glass membrane deformation assembly of claim 24 further comprising:
curing the glass membrane deformation assembly.

25. The method of producing a glass membrane deformation assembly of claim 22 wherein partially fabricating a glass membrane deformation assembly using MEMS process includes:
affixing a piezoelectric layer to a surface of a deformable glass membrane;
etching a portion of the piezoelectric layer to expose a portion of the surface of the deformable glass membrane;
affixing a structural member to a second surface of the deformable glass membrane; and
etching a portion of the structural member to expose a portion of the second surface of the deformable glass membrane.

26. The method of producing a glass membrane deformation assembly of claim 25 wherein affixing a piezoelectric layer to a surface of a deformable glass membrane include:
sputtering the piezoelectric layer onto the surface of the deformable glass membrane.

27. The method of producing a glass membrane deformation assembly of claim 25 wherein affixing a structural member to a second surface of the deformable glass membrane includes:
affixing the structural member to the second surface of the deformable glass membrane via an epoxy.

28. The method of producing a glass membrane deformation assembly of claim 25 wherein affixing a structural member to a second surface of the deformable glass membrane includes:
bonding the structural member to the second surface of the deformable glass membrane via a bonding technique.
